(19) United States
(12) Patent Application Publication
(10) Pub. No.: US 2023/0360981 A1
(43) Pub. Date: Nov. 9, 2023

(54) MODULE

(71) Applicant: Murata Manufacturing Co., Ltd., Nagaokakyo-shi (JP)

(72) Inventors: Shota HAYASHI, Nagaokakyo-shi (JP); Nobuaki OGAWA, Nagaokakyo-shi (JP); Yuki ASANO, Nagaokakyo-shi (JP)

(21) Appl. No.: 18/351,550

(22) Filed: Jul. 13, 2023

Related U.S. Application Data
(63) Continuation of application No. PCT/JP2021/048085, filed on Dec. 24, 2021.

(30) Foreign Application Priority Data
Jan. 15, 2021 (JP) 2021-005114

(51) Int. Cl. H01L 23/06; H01L 25/16; H01L 23/31; H01L 23/00

(52) U.S. Cl. CPC H01L 23/06; H01L 25/165; H01L 23/3142; H01L 24/16; H01L 2224/16227; H01L 2224/16238; H01L 2924/19105

(57) ABSTRACT

A module includes a substrate having an upper main surface and a lower main surface arranged in an up-down direction, and a metal member including a plate-shaped portion provided on the upper main surface of the substrate, the plate-shaped portion having a front main surface, a back main surface, and a lower end surface arranged in the front-back direction when viewed in the up-down direction. The lower end surface of the plate-shaped portion includes a straight portion extending in the left-right direction and one or more protruding portions protruding in the forward direction or the backward direction with respect to the straight portion, and the straight portion and the one or more protruding portions are visually recognized when viewed in the upward direction.

### CROSS REFERENCE TO RELATED APPLICATION

This is a continuation of International Application No. PCT/JP2021/048085 filed on Dec. 24, 2021 which claims priority from Japanese Patent Application No. 2021-005114 filed on Jan. 15, 2021. The contents of these applications are incorporated herein by reference in their entireties.

### BACKGROUND OF THE DISCLOSURE

### Field of the Disclosure

The present disclosure relates to a module including a substrate on which an electronic component is mounted.

### Description of the Related Art

As a disclosure related to the module according to the related art, for example, a circuit module described in Patent Literature 1 is known. The circuit module includes a circuit board, a plurality of electronic components, a conductive partition, and an insulating resin layer.

The circuit board has a plate shape having an upper main surface. The conductive partition is provided on the upper main surface of the circuit board. The conductive partition is one metal plate extending in an upward direction from the upper main surface of the circuit board. The conductive partition includes a first component, a second component, and a third component. The first component and the second component extend in the left-right direction when viewed in the up-down direction. The first component is provided on the right front of the second component. The front end of the third component is connected to the left end of the first component. The back end of the third component is connected to the right end of the second component. As described above, the conductive partition has a structure in which one metal plate is bent at two points of the boundary between the first component and the third component and the boundary between the second component and the third component. Thus, the conductive partition divides the space on the circuit board into a first block and a second block. The first block is the space before the conductive partition. The second block is the space after the conductive partition.

Some of the plurality of electronic components are provided in the first block. The rest of the plurality of electronic components are provided in the second block. The insulating resin layer covers the plurality of electronic components and the conductive partition. In such a circuit module described in Patent Literature 1, electromagnetic interference between some of the plurality of electronic components and the rest of the plurality of electronic components is suppressed by the conductive partition.

In the circuit module described in Patent Literature 1, the conductive partition includes a third component extending in the front-back direction. Thus, the electronic partition is prevented from falling in the forward direction or a backward direction.
[Patent Literature 1]
   Japanese Patent Unexamined Publication No. 2011-258886 bulletin

### BRIEF SUMMARY OF THE DISCLOSURE

By the way, in the circuit module described in Patent Literature 1, there is a demand for reducing the size of the circuit module while preventing the conductive partition from falling in a forward direction or a backward direction.

Therefore, a possible benefit of the present disclosure is to provide a module capable of reducing the size of the module while preventing the metal member from falling.

A module according to an embodiment of the present disclosure includes: a substrate having an upper main surface and a lower main surface arranged in an up-down direction; a metal member including a plate-shaped portion provided on the upper main surface of the substrate, the plate-shaped portion having a front main surface and a back main surface arranged in a front-back direction when viewed in an up-down direction and a lower end surface connected to the front main surface and the back main surface; a first electronic component mounted on the upper main surface of the substrate and disposed in front of the metal member; a second electronic component mounted on the upper main surface of the substrate and disposed behind the metal member; and a sealing resin layer provided on the upper main surface of the substrate and covering the metal member, the first electronic component, and the second electronic component. The lower end surface of the plate-shaped portion includes a straight portion extending in a left-right direction and one or more protruding portions extending in a forward direction or a backward direction with respect to the straight portion. The straight portion and the one or more protruding portions are visually recognized when viewed in an upward direction.

According to the module of the present disclosure, it is possible to reduce the size of the module while preventing the metal member from falling.

### BRIEF DESCRIPTION OF THE SEVERAL VIEWS OF THE DRAWINGS

FIG. 1 is a perspective view of a module 10.

FIG. 2 is a top view of the module 10.

FIG. 3 is a cross-sectional view of the module 10 taken along line A-A.

FIG. 4 is a cross-sectional view of the module 10 taken along line B-B.

FIG. 5 is a perspective view and an enlarged view of a metal member 14.

FIG. 6 is a view illustrating a lower end surface SD3 of the metal member 14.

FIG. 7 is a cross-sectional view of the metal member 14 and a mounting electrode 12a.

FIG. 8 is a top view of the metal member 14 and the mounting electrode 12a.

FIG. 9 is a view combining a rear view of the metal member 14 and a cross-sectional view of the substrate 12.

FIG. 10 is a perspective view at the time of mounting the metal member 14.

FIG. 11 is a cross-sectional view at the time of mounting the metal member 14.

FIG. 12 is a cross-sectional view at the time of mounting the metal member 14.

FIG. 13 is a cross-sectional view at the time of mounting the metal member 14.

FIG. 14 is a cross-sectional view at the time of mounting the metal member 14.

FIG. 15 is a cross-sectional view at the time of manufacturing the module 10.

FIG. 16 is a cross-sectional view at the time of manufacturing the module 10.

FIG. 17 is an enlarged view of a metal member 14a.

FIG. 18 is an enlarged view of a metal member 14b.

FIG. 19 is a cross-sectional view of the metal member 14b.

FIG. 20 is a top view of a metal member 14c.

FIG. 21 is a top view of a metal member 14d.

FIG. 22 is a top view of a metal member 14e.

FIG. 23 is a top view of a metal member 14f and an enlarged view of the metal member 14f.

FIG. 24 is a top view of a metal member 14g and an enlarged view of the metal member 14g.

FIG. 25 is a top view of the metal member 14 and a mounting electrode 12a of a module 10a.

FIG. 26 is a top view of the metal member 14 and the mounting electrode 12a of a module 10b.

FIG. 27 is a top view of the metal member 14 and the mounting electrode 12a of the module 10c.

FIG. 28 is a rear view of a metal member 14h.

FIG. 29 is a cross-sectional view of the metal member 14 of a module 10d.

FIG. 30 is a cross-sectional view of the metal member 14b of a module 10e.

FIG. 31 is a cross-sectional view of the metal member 14b of a module 10f.

FIG. 32 is a cross-sectional view of a metal member 14i of a module 10g.

FIG. 33 is a cross-sectional view of the metal member 14i of a module 10h.

FIG. 34 is a perspective view of a metal member 14j.

FIG. 35 is a view illustrating a lower end surface SD3 of the metal member 14j.

### DETAILED DESCRIPTION OF THE DISCLOSURE

### Embodiments

### [Structure of Module]

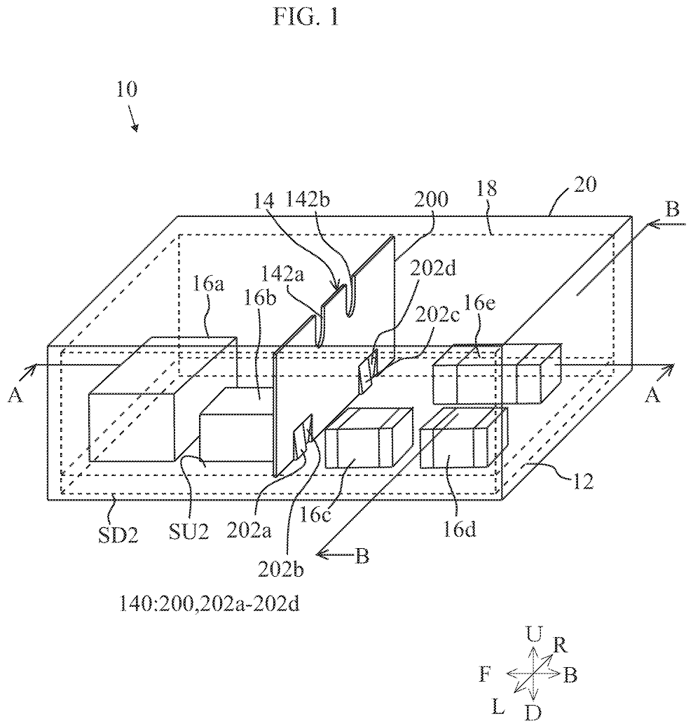

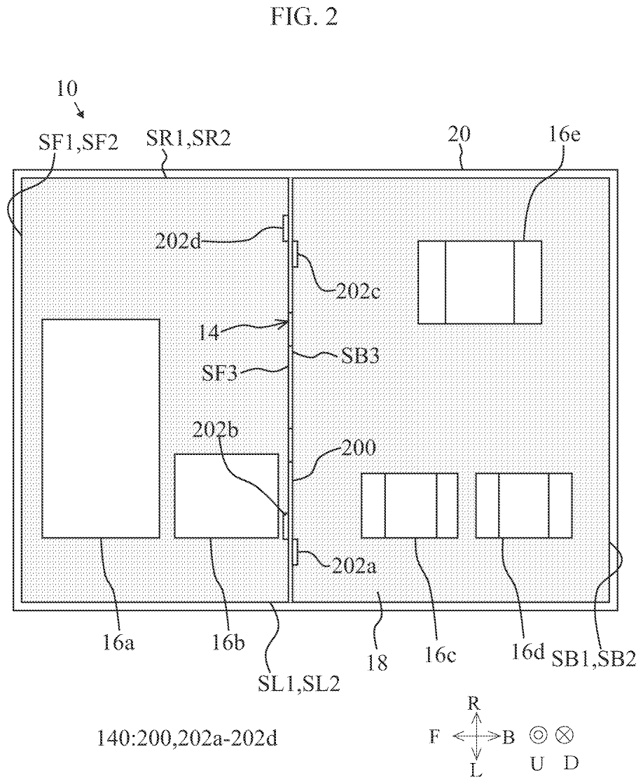

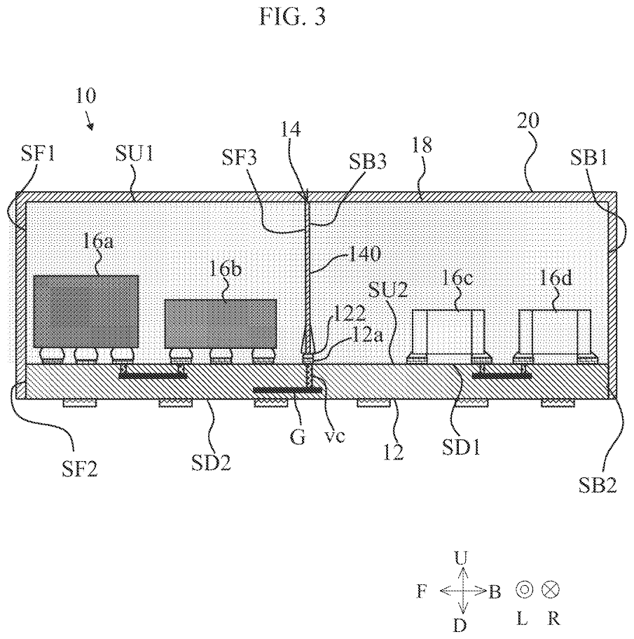

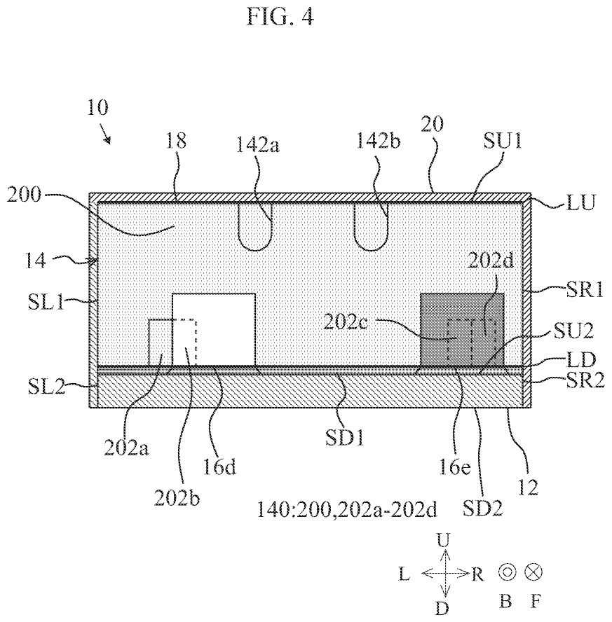

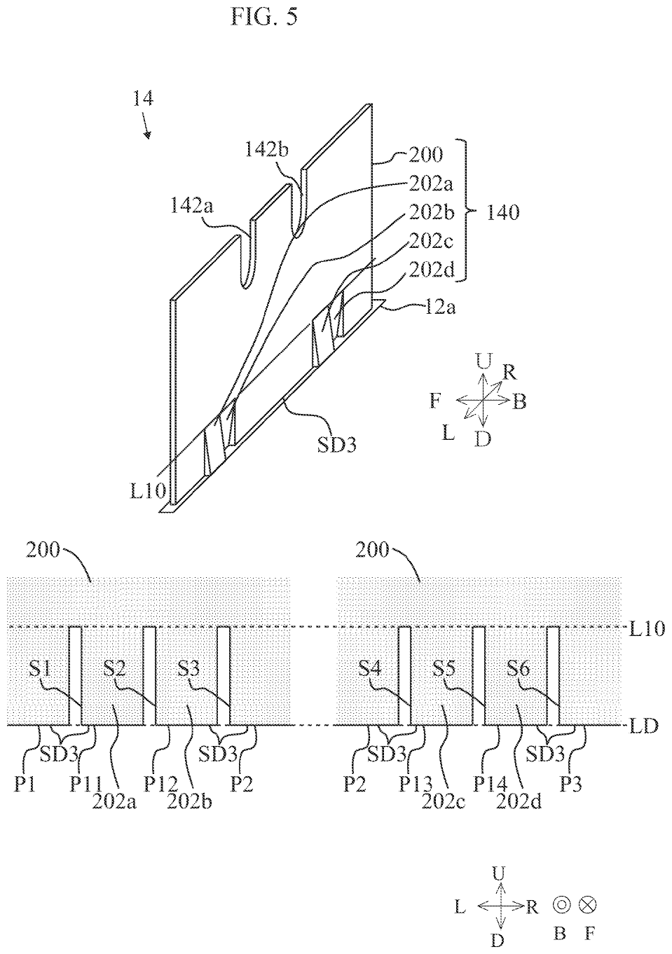

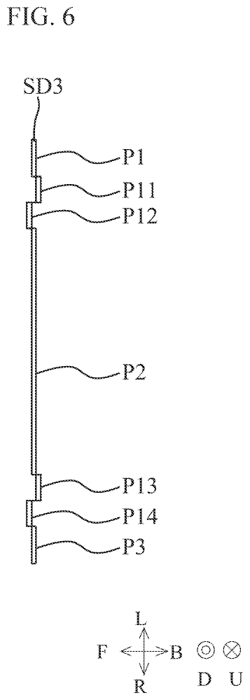

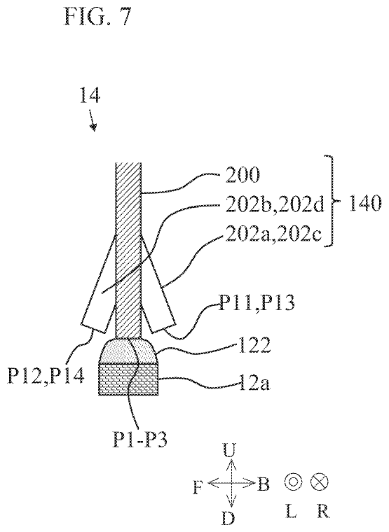

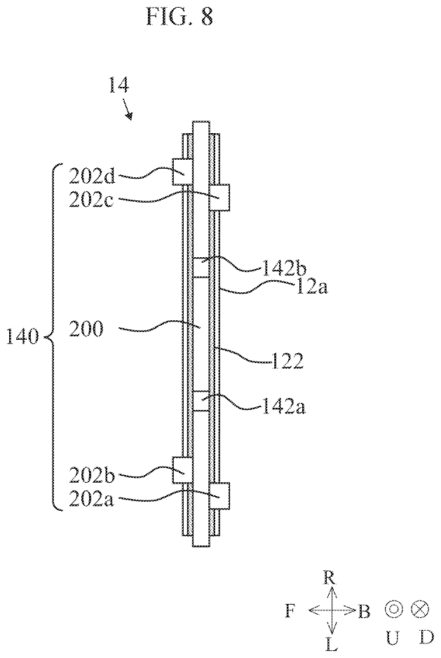

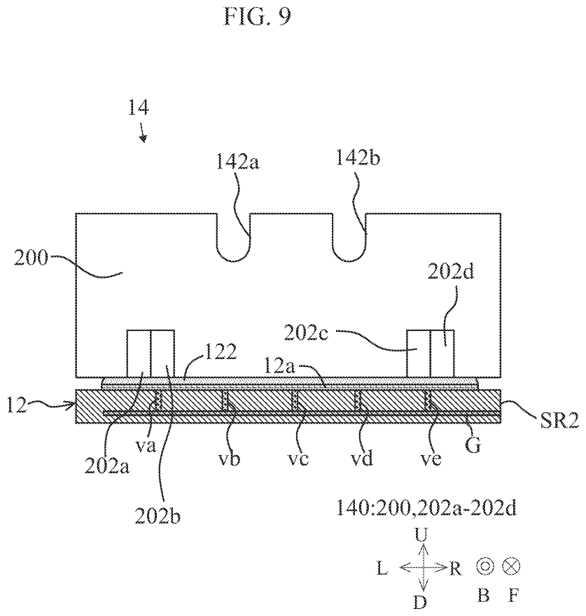

Hereinafter, a structure of a module 10 according to an embodiment of the present disclosure will be described with reference to the drawings. FIG. 1 is a perspective view of the module 10. In FIG. 1, the inside of the module 10 is seen through. FIG. 2 is a top view of the module 10. In FIG. 2, the inside of the module 10 is seen through. FIG. 3 is a cross-sectional view of the module 10 taken along line A-A. FIG. 4 is a cross-sectional view of the module 10 taken along line B-B. FIG. 5 is a perspective view and an enlarged view of a metal member 14. In the enlarged view of FIG. 5, support portions 202a to 202d are not bent. FIG. 6 is a view illustrating a lower end surface SD3 of the metal member 14. FIG. 7 is a cross-sectional view of the metal member 14 and a mounting electrode 12a. FIG. 8 is a top view of the metal member 14 and the mounting electrode 12a. In FIG. 8, the metal member 14 and the mounting electrode 12a are extended 3 times in the front-back direction so that the structure can be easily visually recognized. FIG. 9 is a view combining a rear view of the metal member 14 and a cross-sectional view of the substrate 12.

Hereinafter, the direction in the module 10 will be described. As illustrated in FIG. 1, a substrate 12 of the module 10 has a plate shape. Therefore, the direction in which an upper main surface SU2 and a lower main surface SD2 of the substrate 12 are arranged is defined as an up-down direction. As illustrated in FIG. 2, when viewed in the up-down direction, a direction in which a front main surface SF3 and a back main surface SB3 of a plate-shaped portion 140 of the metal member 14 are arranged is defined as a front-back direction. In addition, a direction orthogonal to the front-back direction and the up-down direction is defined as a left-right direction. The up-down direction, the left-right direction, and the front-back direction are orthogonal to each other. However, the up-down direction, the left-right direction, and the front-back direction may not coincide with the up-down direction, the left-right direction, and the front-back direction in actual use of the module 10. In each drawing, the upward direction and the downward direction may be exchanged, the left direction and the right direction may be exchanged, or the forward direction and the backward direction may be exchanged.

Hereinafter, definitions of terms in the present specification will be described. First, a positional relationship of members in the present specification will be defined. X to Z are members or parts constituting the module 10. In the present specification, X and Y arranged in the front-back direction indicate the following states. When X and Y are viewed in a direction perpendicular to the front-back direction, both X and Y are arranged on an arbitrary straight line indicating the front-back direction. In the present specification, X and Y arranged in the front-back direction when viewed in the up-down direction indicate the following states. When X and Y are viewed in the up-down direction, both X and Y are arranged on an arbitrary straight line indicating the front-back direction. In this case, when X and Y are viewed from the left-right direction different from the up-down direction, one of X and Y may not be arranged on arbitrary straight line indicating the front-back direction. X and Y may be in contact with each other. X and Y may be separated from each other. Z may be present between X and Y. This definition also applies to directions other than the front-back direction.

In the present specification, arranging X before Y refers to the following state. At least a part of X is disposed in a region through which Y passes when Y translates in the forward direction. Therefore, X may be within the region through which Y passes when Y translates in the forward direction, or may protrude from the region through which Y passes when Y translates in the forward direction. In this case, X and Y are aligned in the front-back direction. This definition also applies to directions other than the front-back direction.

In the present specification, arranging X in front of Y refers to the following state. X is disposed in front of a plane passing through the front end of Y and orthogonal to the front-back direction. In this case, X and Y may be arranged in the front-back direction or may not be arranged in the front-back direction. This definition also applies to directions other than the front-back direction.

In the present specification, “X and Y are electrically connected” means that electricity is conducted between X and Y. Therefore, X and Y may be in contact with each other, or X and Y may not be in contact with each other. When X and Y are not in contact with each other, Z having conductivity is disposed between X and Y.

The module 10 is, for example, a high frequency module. The high frequency module is, for example, an analog front end module of a portable wireless communication device. However, the module 10 is not limited to the high frequency module. As illustrated in FIGS. 1 to 4, the module 10 includes the substrate 12, the metal member 14, electronic components 16a to 16e, a sealing resin layer 18, and a shield 20.

The substrate 12 is, for example, a multilayer wiring substrate having a structure in which a plurality of insulator layers made of a low-temperature co-fired ceramic, a high-temperature co-fired ceramic, glass epoxy, or the like is stacked. The substrate 12 has a plate shape. Therefore, the substrate 12 has the upper main surface SU2, the lower main surface SD2, a left surface SL2, a right surface SR2, a front surface SF2, and a back surface SB2 as illustrated in FIGS. 2 to 4. The upper main surface SU2 and the lower main surface SD2 are arranged in the up-down direction. The substrate 12 has a rectangular shape when viewed in the up-down direction. An electric circuit is provided by a conductor layer and an interlayer connection conductor inside the upper main surface SU2 of the substrate 12, the lower main surface SD2 of the substrate 12, and the substrate 12. However, details of the electric circuit will be described later.

The metal member 14 is provided on the upper main surface SU2 of the substrate 12. The metal member 14 has a structure in which one metal plate is subjected to bending. The metal member 14 is made of, for example, tough pitch copper. Note that brass, phosphor bronze, SUS, aluminum, or the like may be used instead of the tough pitch copper. The thickness of the metal member 14 is, for example, 50 μm. As illustrated in FIGS. 1, 2, 4, and 5, the metal member 14 includes the plate-shaped portion 140. The plate-shaped portion 140 has the front main surface SF3, the back main surface SB3, and the lower end surface SD3. The front main surface SF3 and the back main surface SB3 are arranged in the front-back direction when viewed in the up-down direction. The front main surface SF3 has a normal vector extending in the forward direction. The back main surface SB3 has a normal vector extending in the backward direction. However, these normal vectors may be slightly inclined with respect to the forward direction and the backward direction. The angle formed by these normal vectors and the forward direction and the backward direction is, for example, 70° or more and 110° or less. The plate-shaped portion 140 is provided on the upper main surface SU2 of the substrate 12. The plate-shaped portion 140 extends in the upward direction from the upper main surface SU2 of the substrate 12. The lower end surface SD3 is a surface connected to the front main surface SF3 and the back main surface SB3.

As illustrated in FIG. 4, the plate-shaped portion 140 has a rectangular shape when viewed in the front-back direction. However, the plate-shaped portion 140 is provided with plate-shaped portion upper notches 142a and 142b. Therefore, strictly speaking, the plate-shaped portion 140 has a shape different from the rectangular shape when viewed in the front-back direction. Therefore, as illustrated in FIG. 4, when viewed in the front-back direction, a line connecting the upper end of the plate-shaped portion 140 in the left-right direction is defined as a plate-shaped portion upper side LU. When viewed in the front-back direction, a line connecting the lower end of the plate-shaped portion 140 in the left-right direction is defined as a plate-shaped portion lower side LD. The plate-shaped portion upper side LU is located on the plate-shaped portion lower side LD. In addition, in the present specification, the notch is a recess formed in the outer edge of the plate-shaped portion 140 by partially missing the plate-shaped portion 140. The notch in the present specification includes, for example, a U-shaped defect extending from a side of a rectangular plate in a direction orthogonal to the side and an angular U-shaped defect.

The plate-shaped portion upper notches 142a and 142b extend in the downward direction from the plate-shaped portion upper side LU. The plate-shaped portion upper notches 142a and 142b have a U-shape when viewed in the front-back direction. That is, the plate-shaped portion upper notches 142a and 142b have a shape in which a rectangle having an upper side, a lower side, a left side, and a right side and a semicircle protruding in the downward direction from the upper side of the rectangle are combined. The lower ends of the plate-shaped portion upper notches 142a and 142b are located above the center of the plate-shaped portion 140 in the up-down direction when viewed in the front-back direction. The plate-shaped portion upper notch 142a is located on the left of the plate-shaped portion upper notch 142b. The lengths in the up-down direction of the plate-shaped portion upper notches 142a and 142b are, for example, half or less of the length in the up-down direction of the plate-shaped portion 140. The widths of the plate-shaped portion upper notches 142a and 142b in the left-right direction are, for example, 150 μm.

As illustrated in FIG. 6, the lower end surface SD3 of the plate-shaped portion 140 includes straight portions P1 to P3 and protruding portions P11 to P14. The straight portions P1 to P3 extend in the left-right direction. The straight portions P1 to P3 are arranged in a line in this order from left to right. The protruding portions P11 and P13 protrude in the backward direction with respect to the straight portions P1 to P3. The protruding portions P12 and P14 protrude in the forward direction with respect to the straight portions P1 to P3. The protruding portion P11 is located on the right of the straight portion P1. The protruding portion P12 is located on the left of the straight portion P2. The protruding portion P11 and the protruding portion P12 are adjacent to each other in the left-right direction. In this manner, each of the protruding portions P11 and P12 not including the left end and the right end of the lower end surface SD3 of the plate-shaped portion 140 is defined as a first intermediate protruding portion and a second intermediate protruding portion. The protruding portion P13 is located on the right of the straight portion P2. The protruding portion P14 is located on the left of the straight portion P3. The protruding portion P13 and the protruding portion P14 are adjacent to each other in the left-right direction. In this manner, each of the protruding portions P13 and P14 not including the left end and the right end of the lower end surface SD3 of the plate-shaped portion 140 is defined as a first intermediate protruding portion and a second intermediate protruding portion. The straight portions P1 to P3 and the protruding portions P11 to P14 of the plate-shaped portion 140 as described above are visually recognized when viewed in the upward direction. The plate-shaped portion 140 has a structure described below such that the lower end surface SD3 of the plate-shaped portion 140 has such a structure.

As illustrated in FIG. 5, the plate-shaped portion 140 includes a plate-shaped main body 200 and the support portions 202a to 202d. The plate-shaped main body 200 occupies most of the plate-shaped portion 140. The plate-shaped main body 200 has a flat plate shape. Therefore, the plate-shaped main body 200 is not bent. The plate-shaped main body 200 is not curved. The plate-shaped main body 200 includes the straight portions P1 to P3.

The support portions 202a to 202d are provided at the lower end portion of the plate-shaped portion 140. The support portions 202a and 202b are provided on the left part of the plate-shaped portion 140. The support portions 202c and 202d are provided on the right part of the plate-shaped portion 140. The support portion 202a and the support portion 202b are adjacent to each other in the left-right direction. The support portion 202c and the support portion 202d are adjacent to each other in the left-right direction.

Each of the support portions 202a to 202d includes the protruding portions P11 to P14. As described above, the protruding portions P11 to P14 (first intermediate protruding portions) do not include the left end and the right end of the lower end surface SD3 of the plate-shaped portion 140. The support portions 202a and 202c including the protruding portions P11 and P13 (first intermediate protruding portions) not including the left end and the right end of the lower end surface SD3 of the plate-shaped portion 140 are defined as first intermediate support portions. The support portions 202b and 202d including the protruding portions P12 and P14 (second intermediate protruding portions) not including the left end and the right end of the lower end surface SD3 of the plate-shaped portion 140 are defined as second intermediate support portions. The support portion 202a as the first intermediate support portion and the support portion 202b as the second intermediate support portion are adjacent to each other in the left-right direction. The support portion 202c as the first intermediate support portion and the support portion 202d as the second intermediate support portion are adjacent to each other in the left-right direction.

A slit S1 extending in the upward direction from the plate-shaped portion lower side LD is provided on the left of the support portion 202a. Thus, the slit S1 (first slit) is provided between the plate-shaped main body 200 and the support portion 202a (first intermediate support portion). A slit S3 extending in the upward direction from the plate-shaped portion lower side LD is provided on the right of the support portion 202b. Thus, the slit S3 (third slit) is provided between the plate-shaped main body 200 and the support portion 202b (second intermediate support portion). Further, a slit S2 extending in the upward direction from the plate-shaped portion lower side LD is provided on the right of the support portion 202a and on the left of the support portion 202b. Thus, the slit S2 (second slit) is provided between the support portion 202a (first intermediate support portion) and the support portion 202b (second intermediate support portion).

A slit S4 extending in the upward direction from the plate-shaped portion lower side LD is provided on the left of the support portion 202c. Thus, the slit S4 (first slit) is provided between the plate-shaped main body 200 and the support portion 202c (first intermediate support portion). A slit S6 extending in the upward direction from the plate-shaped portion lower side LD is provided on the right of the support portion 202d. Thus, the slit S6 (third slit) is provided between the plate-shaped main body 200 and the support portion 202d (second intermediate support portion). Further, a slit S5 extending in the upward direction from the plate-shaped portion lower side LD is provided on the right of the support portion 202c and on the left of the support portion 202d. Thus, the slit S5 (second slit) is provided between the support portion 202c (first intermediate support portion) and the support portion 202d (second intermediate support portion). In the present specification, the slit is a space formed by providing a notch in the metal member 14 before bending. Note that the slit may be not only a space formed by providing a notch in the metal member 14 but also a space formed by providing a thin groove in the metal member 14.

The support portions 202a and 202c are bent in the backward direction with respect to the plate-shaped main body 200. Thus, the support portions 202a and 202c (first intermediate protruding portions) protrude in the backward direction with respect to the plate-shaped main body 200. As a result, the protruding portions P11 and P13 protrude in the backward direction with respect to the straight portions P1 to P3. The support portions 202b and 202d are bent in the forward direction with respect to the plate-shaped main body 200. Thus, the support portions 202b and 202d (second intermediate protruding portions) protrude in the forward direction with respect to the plate-shaped main body 200. As a result, the protruding portions P12 and P14 protrude in the forward direction with respect to the straight portions P1 to P3.

The polygonal line of the support portions 202a to 202d is a straight line L10 connecting the upper ends of the slits S1 to S6. Therefore, the support portion 202a has a rectangular shape surrounded by the slits S1 and S2, the plate-shaped portion lower side LD, and the straight line L10. The support portion 202b has a rectangular shape surrounded by the slits S2 and S3, the plate-shaped portion lower side LD, and the straight line L10. The support portion 202c has a rectangular shape surrounded by the slits S4 and S5, the plate-shaped portion lower side LD, and the straight line L10. The support portion 202d has a rectangular shape surrounded by the slits S5 and S6, the plate-shaped portion lower side LD, and the straight line L10.

As illustrated in the enlarged view of FIG. 5, the lengths of the support portions 202a to 202d in the up-down direction are equal to the lengths of the slits S1 to S6 in the up-down direction. Therefore, as illustrated in FIG. 5, in a state where the support portions 202a to 202d are not bent, the positions of the protruding portions P11 to P14 in the up-down direction are the same as the positions of the straight portions P1 to P3 in the up-down direction. Therefore, in a state where the support portions 202a to 202d are bent, the protruding portions P11 to P14 are positioned above the straight portions P1 to P3 as illustrated in FIG. 7.

The metal member 14 configured as described above is fixed to the substrate 12. Hereinafter, fixing of the metal member 14 to the substrate 12 will be described. As illustrated in FIGS. 3 and 5, the substrate 12 includes the mounting electrode 12a located on the upper main surface SU2 of the substrate 12. As illustrated in FIG. 8, the mounting electrode 12a has a rectangular shape having long sides extending in the left-right direction when viewed in the up-down direction.

As illustrated in FIGS. 7 and 8, solder 122 is applied to the upper surface of the mounting electrode 12a. As illustrated in FIG. 7, the solder 122 is attached to the straight portions P1 to P3 of the plate-shaped main body 200. However, the solder 122 is not attached to the protruding portions P11 to P14 of the support portions 202a to 202d. As described above, in the module 10, the straight portions P1 to P3 of the plate-shaped main body 200 are fixed to the mounting electrode 12a by the solder 122.

As illustrated in FIG. 9, the substrate 12 further includes interlayer connection conductors va to ve and a ground conductor layer G. The ground conductor layer G is provided inside the substrate 12. The ground conductor layer G is exposed from the right surface SR2 of the substrate 12.

The interlayer connection conductors va to ve electrically connect the mounting electrode 12a and the ground conductor layer G. The interlayer connection conductors va to ve are arranged in this order from left to right below the metal member 14 as viewed in the front-back direction. The interlayer connection conductors va to ve are arranged at equal intervals under the metal member 14. The interval between the adjacent interlayer connection conductors va to ve is, for example, ¼ of the wavelength of the high frequency signal transmitted through the signal conductor layer (not illustrated) of the substrate 12.

As illustrated in FIGS. 1 and 3, the electronic components 16a and 16b (first electronic components) are mounted on the upper main surface SU2 of the substrate 12. A method for mounting the electronic component 16a is, for example, mounting by soldering. The electronic components 16a and 16b are semiconductor elements such as an IC or a power amplifier (PA), or a chip component such as a chip inductor, a chip capacitor, or a chip resistor. As illustrated in FIG. 2, the electronic components 16a and 16b are disposed in front of the metal member 14. In the present embodiment, the electronic components 16a and 16b are disposed before the metal member 14. Therefore, the electronic components 16a and 16b overlap the metal member 14 when viewed in the front-back direction.

The electronic components 16c to 16e (second electronic components) are mounted on the upper main surface SU2 of the substrate 12. The method for mounting the electronic components 16c to 16e is, for example, mounting by soldering. The electronic components 16c to 16e are semiconductor elements such as an IC and a power amplifier (PA), or a chip component such as a chip inductor, a chip capacitor, or a chip resistor. As illustrated in FIG. 2, the electronic components 16c to 16e are disposed behind the metal member 14. In the present embodiment, the electronic components 16c to 16e are disposed after the metal member 14. Therefore, the electronic components 16c to 16e overlap the metal member 14 when viewed in the front-back direction.

As illustrated in FIGS. 1 and 3, the sealing resin layer 18 is provided on the upper main surface SU2 of the substrate 12. The sealing resin layer 18 covers the metal member 14 and the electronic components 16a to 16e. Thus, the sealing resin layer 18 protects the metal member 14 and the electronic components 16a to 16e. The material of the sealing resin layer 18 is, for example, an epoxy resin. The sealing resin layer 18 has a rectangular parallelepiped shape. Therefore, the sealing resin layer 18 has an upper surface SU1, a lower surface SD1, a left surface SL1, a right surface SR1, a front surface SF1, and a back surface SB1. The left end of the plate-shaped portion 140 is located on the left surface SL1 of the sealing resin layer 18. The right end of the plate-shaped portion 140 is located on the right surface SR1 of the sealing resin layer 18. The upper end of the plate-shaped portion 140 is located on the upper surface SU1 of the sealing resin layer 18. As a result, the upper end, the left end, and the right end of the plate-shaped portion 140 are exposed from the sealing resin layer 18 on the upper surface SU1, the left surface SL1, and the right surface SR1 of the sealing resin layer 18.

The shield 20 covers the upper surface SU1 of the sealing resin layer 18. In the present embodiment, the shield 20 covers the upper surface SU1, the left surface SL1, the right surface SR1, the front surface SF1, and the back surface SB1 of the sealing resin layer 18, and the left surface SL2, the right surface SR2, the front surface SF2, and the back surface SB2 of the substrate 12. The shield 20 is electrically connected to the metal member 14. Specifically, the shield 20 is in contact with a portion where the metal member 14 is exposed from the sealing resin layer 18. Further, the shield 20 is connected to the ground conductor layer G exposed from the right surface SR2 of the substrate 12. Thus, the metal member 14 is electrically connected to the shield 20 via the mounting electrode 12a. Thus, the shield 20 is connected to the ground potential.

The shield 20 has a multilayer structure. Specifically, the shield 20 includes an adhesion layer, a conductive layer, and a protective layer. The adhesion layer, the conductive layer, and the protective layer are stacked in this order from the lower layer to the upper layer. The adhesion layer serves to increase adhesion strength between the conductive layer and the sealing resin layer 18. The material of the adhesion layer is, for example, stainless steel (SUS). The conductive layer serves a shielding function. The material of the conductive layer is, for example, a metal such as Cu, Ag, or Al. The protective layer serves to prevent corrosion of the conductive layer. The material of the protective layer is, for example, SUS.

### [Method for Manufacturing Module]

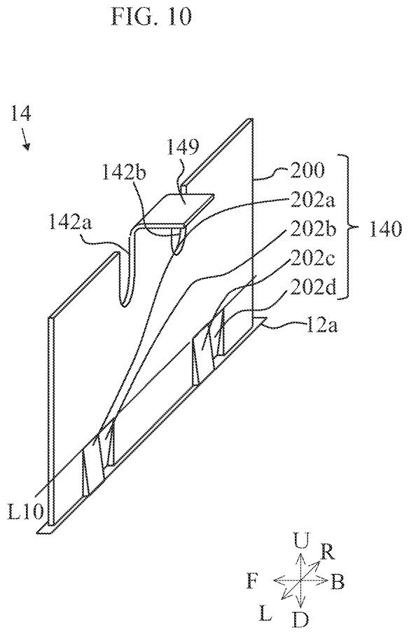

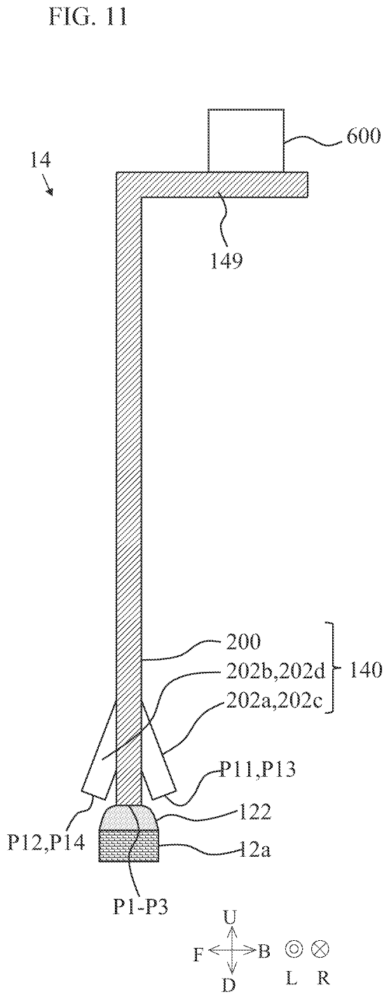

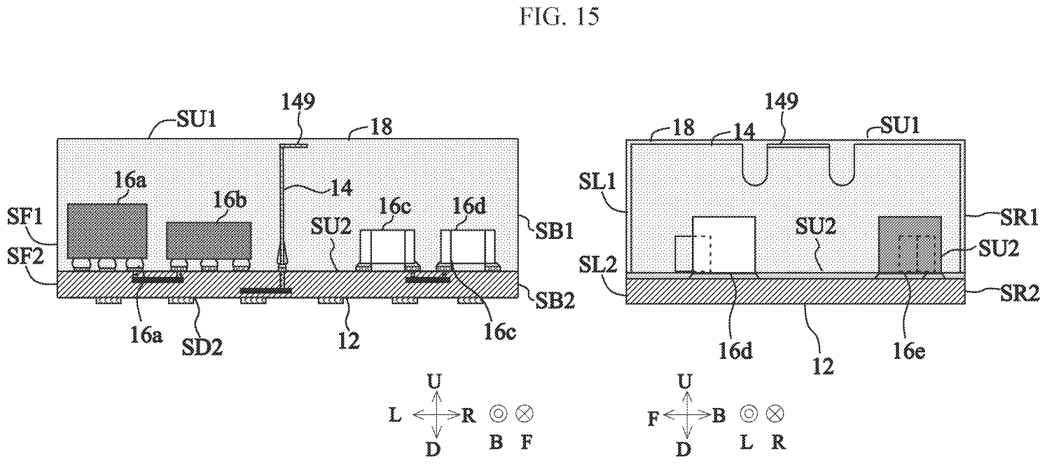

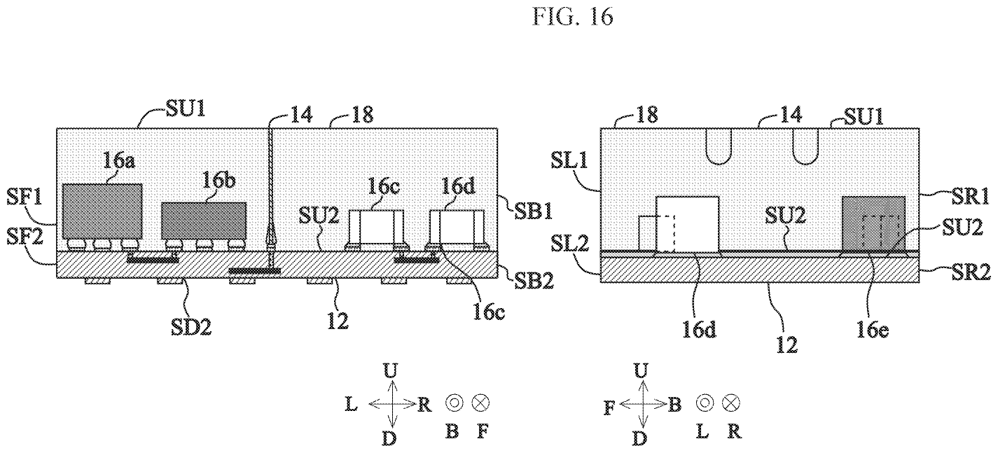

Next, a method for manufacturing the module 10 will be described with reference to the drawings. FIG. 10 is a perspective view at the time of mounting the metal member 14. FIGS. 11 to 14 are cross-sectional views at the time of mounted the metal member 14. FIGS. 15 and 16 are cross-sectional views at the time of manufacturing the module 10.

First, the electronic components 16a to 16e are mounted on the upper main surface SU2 of the substrate 12. Further, as illustrated in FIG. 10, the metal member 14 is mounted on the substrate 12. Here, the metal member 14 at the time of manufacturing the module 10 will be described. The metal member 14 further includes a top surface portion 149. The top surface portion 149 is located between the plate-shaped portion upper notch 142a and the plate-shaped portion upper notch 142b in the left-right direction. The top surface portion 149 extends in the backward direction from the plate-shaped portion upper side LU (see FIG. 4). The top surface portion 149 is formed by bending a part of the metal member 14 in the backward direction. The top surface portion 149 is used for mounting the metal member 14.

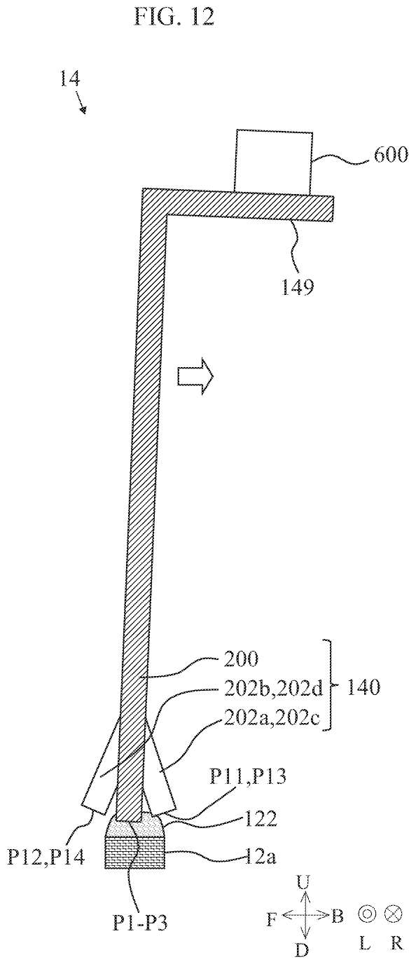

Specifically, as illustrated in FIG. 11, the top surface portion 149 is sucked using a mounting machine 600. Then, the metal member 14 is moved by the mounting machine 600, and the straight portions P1 to P3 of the plate-shaped main body 200 are set on the mounting electrode 12a. At this time, as illustrated in FIG. 12, the metal member 14 is slightly pressed in the downward direction by the mounting machine 600. As a result, the metal member 14 slightly tilts in the backward direction. At this time, the solder 122 adheres to the front main surface and the back main surface of the plate-shaped main body 200. Further, the solder 122 slightly adheres to the support portions 202a and 202c. When the solder 122 adheres to the support portions 202a and 202c, the support portions 202a and 202c function as stoppers against the metal member 14 falling in the forward direction or backward direction. As a result, inclination of the metal member 14 is suppressed.

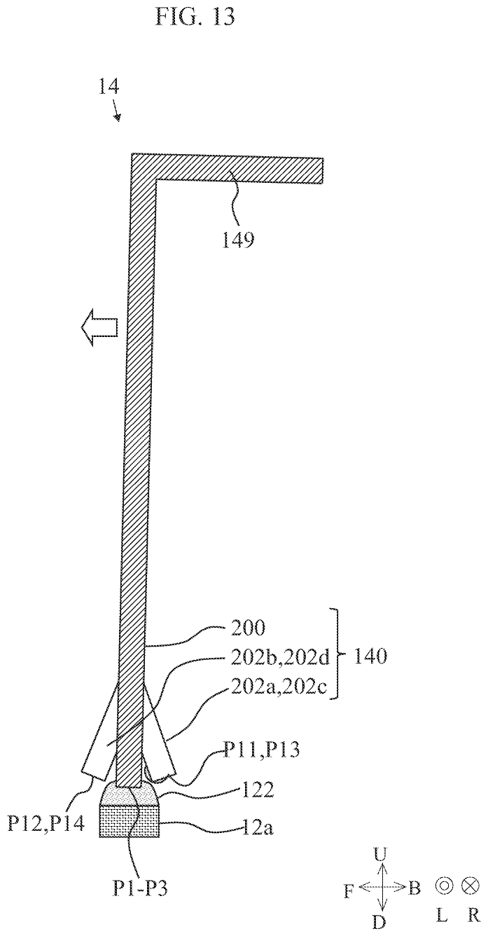

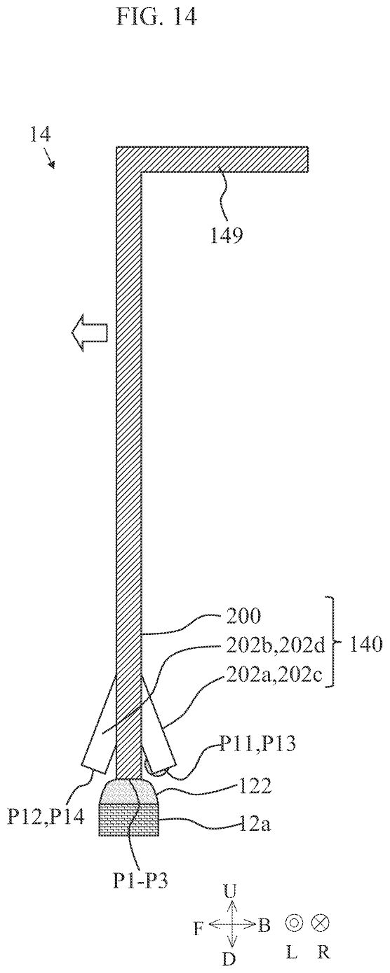

When the mounting machine 600 releases the suction of the top surface portion 149, as illustrated in FIG. 13, the metal member 14 tries to return to the upright state by receiving the reaction force from the substrate 12. Since the front main surface and the back main surface of the plate-shaped main body 200 are wetted with the solder 122, the metal member 14 returns to the upright state by the self-alignment action of the solder 122 as illustrated in FIG. 14.

Next, as illustrated in FIG. 15, the sealing resin layer 18 is formed on the upper main surface SU2 of the substrate 12. At this time, the sealing resin layer 18 is formed so that the sealing resin layer 18 covers the entire upper main surface SU2 of the substrate 12. Specifically, the substrate 12 is set in a mold. Then, a resin (molten resin) which is melted is injected into the mold. At this time, the molten resin passes through the plate-shaped portion upper notches 142a and 142b and spreads over the entire upper main surface SU2 of the substrate 12. Then, the electronic components 16a to 16e and the metal member 14 are located in the sealing resin layer 18. That is, the electronic components 16a to 16e and the metal member 14 are not exposed from the sealing resin layer 18.

Next, as illustrated in FIG. 16, the upper main surface SU of the sealing resin layer 18 is ground with a grindstone. For example, the grindstone grinds the upper surface SU1 of the sealing resin layer 18 while moving in the backward direction with respect to the upper surface SU1 of the sealing resin layer 18. Thus, the upper end of the plate-shaped portion 140 is exposed from the upper surface SU1 of the sealing resin layer 18. When the upper surface SU1 of the sealing resin layer 18 is ground, the top surface portion 149 of the metal member 14 is ground. However, the top surface portion 149 may not be ground.

Further, as illustrated in FIG. 16, by cutting the substrate 12 and the sealing resin layer 18 in the up-down direction using a dicer, the substrate 12 and the sealing resin layer 18 are divided. At this time, the left surface SL1, the right surface SR1, the front surface SF1, and the back surface SB1 of the sealing resin layer 18 are formed.

Next, the shield 20 is formed on the upper surface SU1, the left surface SL1, the right surface SR1, the front surface SF1, and the back surface SB1 of the sealing resin layer 18. Specifically, the adhesion layer, the conductive layer, and the protective layer are formed by performing sputtering three times. As described above, the surface roughness of the upper end, the left end, and the right end of the metal member 14 is larger than the surface roughness of the front main surface SF3 and the back main surface SB3 of the plate-shaped portion 140. Therefore, the adhesion layer adheres to the upper end, the left end, and the right end of the metal member 14 with high adhesion strength. Through the above steps, the module 10 is completed.

### Effects

According to the module 10, it is possible to reduce the size of the module 10 while suppressing the metal member 14 from falling. More specifically, in the module 10, the lower end surface SD3 of the plate-shaped portion 140 includes the straight portions P1 to P3 extending in the left-right direction and one or more protruding portions P11 to P14 protruding in the forward direction or backward direction with respect to the straight portions P1 to P3. As a result, the metal member 14 is supported by the protruding portions P11 to P14 in addition to the straight portions P1 to P3. At this time, the protruding portions P11 to P14 function as stoppers. Thus, the metal member 14 is prevented from falling in the forward direction or backward direction. Further, the straight portions P1 to P3 and the protruding portions P11 to P14 are a part of the plate-shaped portion 140 having a plate shape. The straight portions P1 to P3 and the protruding portions P11 to P14 are visually recognized when viewed in the upward direction. Therefore, the protruding portions P11 to P14 are not portions formed by greatly bending the plate-shaped portion 140 in the forward direction or the backward direction. As a result, the protruding portions P11 to P14 do not greatly protrude in the forward direction or backward direction from the straight portions P1 to P3. Therefore, the protruding portions P11 to P14 do not become too large. Therefore, the size of the plate-shaped portion 140 in the front-back direction decreases. Therefore, the electronic component can be disposed close to the plate-shaped portion 140. Thus, the module 10 can be downsized.

According to the module 10, it is possible to suppress the metal member 14 from falling. More specifically, the slit S1 (first slit) is provided between the plate-shaped main body 200 and the support portion 202a (first intermediate support portion). The slit S3 (third slit) is provided between the plate-shaped main body 200 and the support portion 202b (second intermediate support portion). The slit S2 (second slit) is provided between the support portion 202a (first intermediate support portion) and the support portion 202b (second intermediate support portion). The slit S4 (first slit) is provided between the plate-shaped main body 200 and the support portion 202c (first intermediate support portion). The slit S6 (third slit) is provided between the plate-shaped main body 200 and the support portion 202d (second intermediate support portion). The slit S5 (second slit) is provided between the support portion 202c (first intermediate support portion) and the support portion 202d (second intermediate support portion). As a result, the molten resin can pass through the slits S1 to S6. As a result, the force applied to the metal member 14 by the molten resin decreases. As described above, according to the module 10, it is possible to suppress the metal member 14 from falling.

According to the module 10, in the substrate 12, the shielding property between the region in front of the metal member 14 and the region behind the metal member 14 is improved. More specifically, the substrate 12 includes the interlayer connection conductors va to ve and the ground conductor layer G. The interlayer connection conductors va to ve are arranged at equal intervals under the metal member 14. The interval between the adjacent interlayer connection conductors va to ve is, for example, ¼ of the wavelength of the high frequency signal transmitted through the signal conductor layer (not illustrated) of the substrate 12. As a result, the electromagnetic wave of the high frequency signal transmitted through the signal conductor layer attempts to generate a standing wave in the interlayer connection conductors va to ve. However, the interlayer connection conductors va to ve are connected to the ground conductor layer G. Therefore, the electromagnetic wave of the high frequency signal transmitted through the signal conductor layer flows to the ground via the interlayer connection conductors va to ve and the ground conductor layer G. Therefore, the electromagnetic wave of the high frequency signal transmitted through the signal conductor layer hardly passes through the interlayer connection conductors va to ve in the front-back direction. As a result, according to the module 10, in the substrate 12, the shielding property between the region in front of the metal member 14 and the region behind the metal member 14 is improved.

According to the module 10, it is possible to suppress the metal member 14 from falling at the time of forming the sealing resin layer 18. More specifically, the plate-shaped portion 140 is provided with the plate-shaped portion upper notches 142a and 142b. As a result, the magnitude of the force applied to the plate-shaped portion 140 by the molten resin approaches uniformity over the entire plate-shaped portion 140. As a result, according to the module 10, it is possible to suppress the metal member 14 from falling at the time of forming the sealing resin layer 18.

According to the module 10, the metal member 14 is suppressed from greatly tilting in the front-back direction. More specifically, the plate-shaped portion 140 forms an angle substantially perpendicular to the substrate 12. Thus, the solder 122 is uniformly attached to the front main surface and the back main surface of the plate-shaped main body 200. Therefore, the magnitude of the force by which the plate-shaped main body 200 is pulled in the forward direction by the surface tension of the solder 122 is substantially equal to the magnitude of the force by which the plate-shaped main body 200 is pulled in the backward direction by the surface tension of the solder 122. As a result, the metal member 14 is suppressed from greatly tilting in the front-back direction.

In the module 10, the solder 122 is provided before the protruding portions P11 and P13. As a result, the solder 122 is wetted on the front surfaces of the support portions 202a and 202c. Therefore, when the metal member 14 is mounted, the support portions 202a and 202c are pulled in the forward direction by the solder 122. On the other hand, the solder 122 is provided after the protruding portions P12 and P14. As a result, the solder 122 is wetted on the back surfaces of the support portions 202b and 202d. Therefore, when the metal member 14 is mounted, the support portions 202b and 202d are pulled in the backward direction by the solder 122. Therefore, the force in the forward direction and the force in the backward direction acting on the metal member 14 are offset. As a result, the metal member 14 is mounted in an upright state.

In the module 10, the mounting electrode 12a includes one electrode. Thus, the interlayer connection conductors va to ve are electrically connected by the mounting electrode 12a. Therefore, the interlayer connection conductors va to ve may be arranged in any manner as long as the interlayer connection conductors va to ve are connected to the mounting electrode 12a. That is, the degree of freedom in arrangement of the interlayer connection conductors va to ve is increased. As a result, it is easy to adopt the arrangement of the interlayer connection conductors va to ve that improves the shielding property.

### First Modification

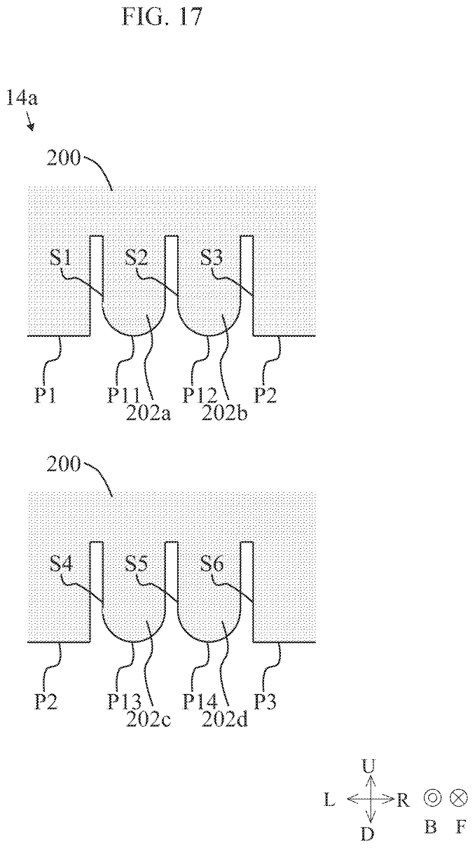

Hereinafter, a metal member 14a according to a first modification will be described with reference to the drawings. FIG. 17 is an enlarged view of the metal member 14a.

The metal member 14a differs from the metal member 14 in the shapes of the support portions 202a to 202d. More specifically, in the metal member 14a, the support portions 202a to 202d are chamfered. Therefore, the lower end portions of the support portions 202a to 202d have a semicircular shape protruding in the downward direction as viewed in the front-back direction. As a result, a region where the molten resin can pass through the metal member 14a in the front-back direction is widened. As a result, the metal member 14a is suppressed from falling. Since other structures of the metal member 14a are the same as those of the metal member 14, the description thereof will be omitted.

### Second Modification

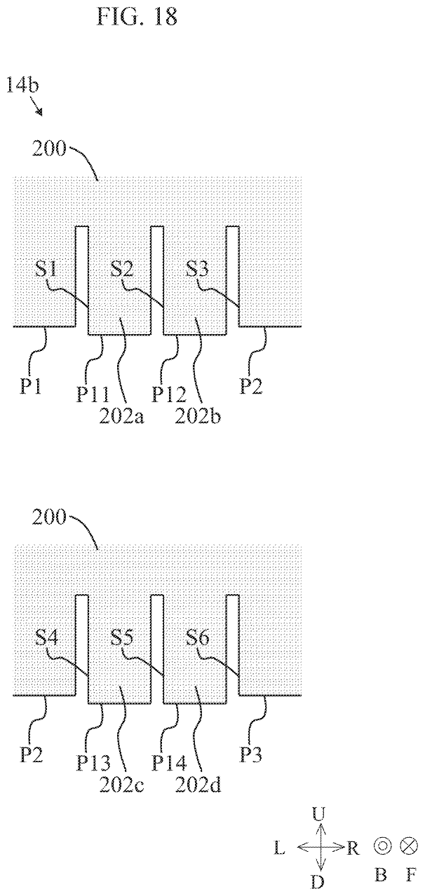

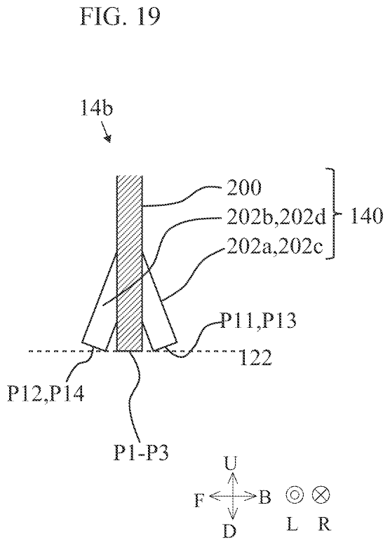

Hereinafter, a metal member 14b according to a second modification will be described with reference to the drawings. FIG. 18 is an enlarged view of the metal member 14b. FIG. 19 is a cross-sectional view of the metal member 14b.

The metal member 14b is different from the metal member 14 in the shapes of the support portions 202a to 202d. More specifically, the lengths of the support portions 202a to 202d of the metal member 14b in the up-down direction are longer than the lengths of the support portions 202a to 202d of the metal member 14 in the up-down direction. As a result, in a state where the support portions 202a to 202d are bent, the positions in the direction of the lower ends of the support portions 202a to 202d in the up-down direction are the same as the positions in the direction of the lower end of the plate-shaped main body 200 in the up-down direction. Therefore, the metal member 14b is easily supported by the support portions 202a to 202d. As a result, the metal member 14b is suppressed from falling. Since other structures of the metal member 14b are the same as those of the metal member 14, the description thereof will be omitted.

### Third Modification

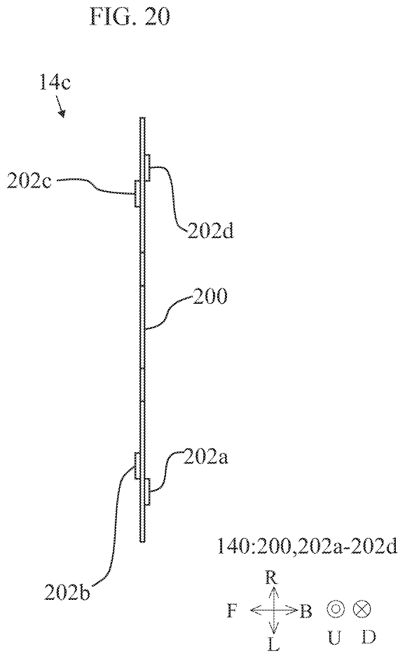

Hereinafter, a metal member 14c according to a third modification will be described with reference to the drawings. FIG. 20 is a top view of the metal member 14c.

The metal member 14c is different from the metal member 14 in the layout of the support portions 202a to 202d. In the metal member 14c, the support portions 202a and 202d protrude with respect to the plate-shaped main body 200 in the backward direction. The support portions 202b and 202c protrude with respect to the plate-shaped main body 200 in the forward direction. Since other structures of the metal member 14c are the same as that of the metal member 14, the description thereof will be omitted.

### Fourth Modification

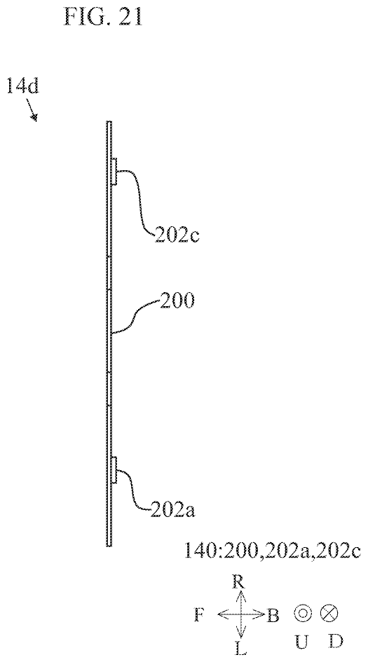

Hereinafter, a metal member 14d according to a fourth modification will be described with reference to the drawings. FIG. 21 is a top view of the metal member 14d.

The metal member 14d is different from the metal member 14 in that the support portions 202b and 202d are not provided. The metal member 14d includes the support portions 202a and 202c. The support portions 202a and 202c protrude with respect to the plate-shaped main body 200 in the backward direction. As described above, in the metal member 14d, the support portions 202a and 202c protrude only in the backward direction with respect to the plate-shaped main body 200. Since other structures of the metal member 14d are the same as that of the metal member 14, the description thereof will be omitted.

### Fifth Modification

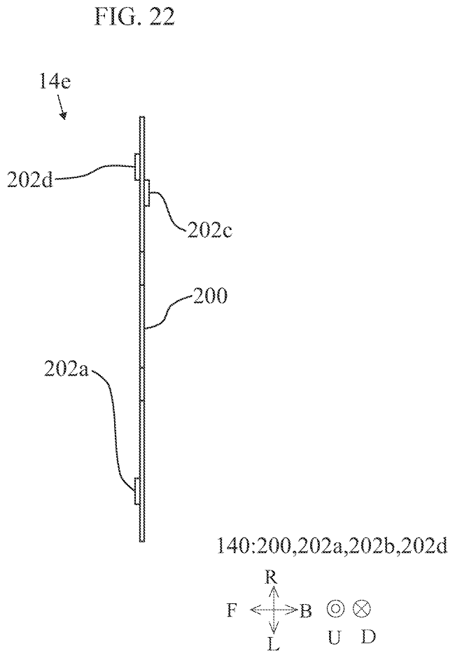

Hereinafter, a metal member 14e according to a fifth modification will be described with reference to the drawings. FIG. 22 is a top view of the metal member 14e.

The metal member 14e is different from the metal member 14 in that the support portion 202b is not provided. Since other structures of the metal member 14e are the same as those of the metal member 14, the description thereof will be omitted.

### Sixth Modification

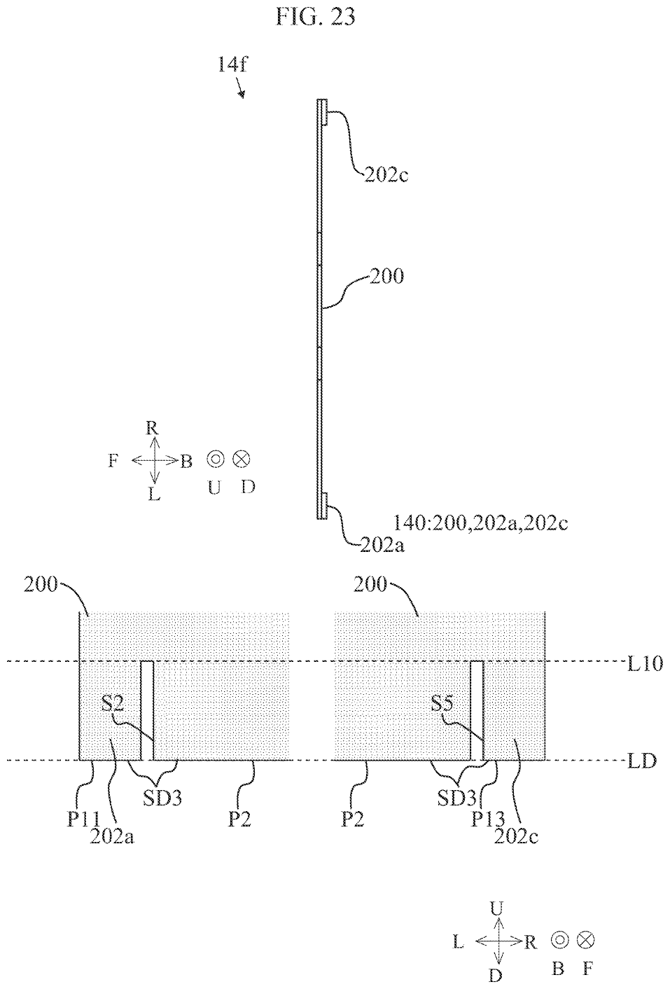

Hereinafter, a metal member 14f according to a sixth modification will be described with reference to the drawings. FIG. 23 is a top view of the metal member 14f and an enlarged view of the metal member 14f.

The metal member 14f is different from the metal member 14d at the positions of the support portions 202a and 202c. In the metal member 14f, the support portion 202a is located at the left end portion of the metal member 14f. The support portion 202c is located at the right end portion of the metal member 14f. Details will be described below.

The protruding portions P11 and P13 including the left end or the right end of the lower end surface SD3 of the plate-shaped portion 140 are defined as end protruding portions. The support portions 202a and 202c including the protruding portions P11 and P13 (end protruding portions) are defined as end support portions. At this time, one slit S2 is provided between the plate-shaped main body 200 and the support portion 202a (end support portion). One slit S5 is provided between the plate-shaped main body 200 and the support portion 202c (end support portion). Since other structures of the metal member 14f are the same as those of the metal member 14d, the description thereof will be omitted.

According to the metal member 14f, one slit S2 may be formed in order to form the protruding portion P11. In addition, one slit S5 may be formed to form the protruding portion P13. Therefore, the metal member 14f can be easily manufactured.

### Seventh Modification

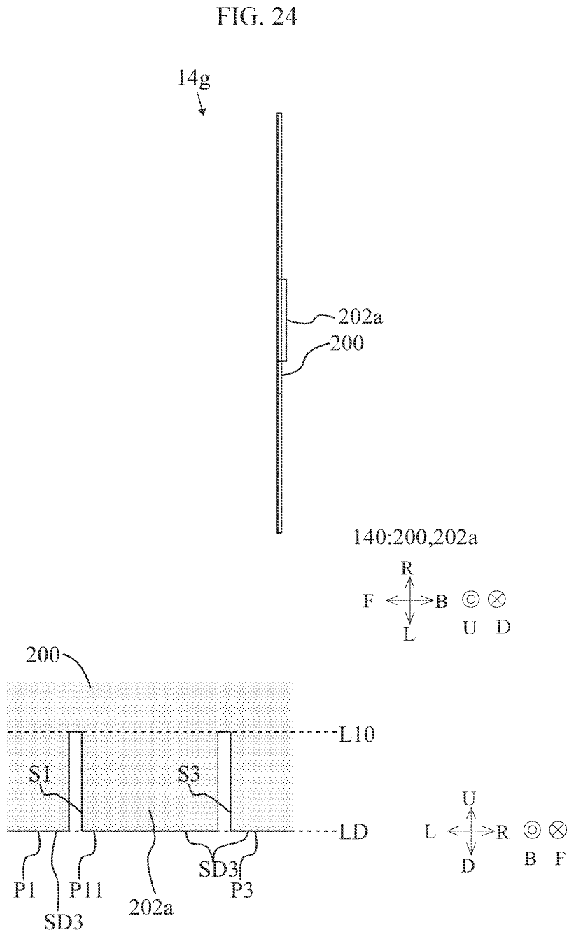

Hereinafter, a metal member 14g according to a seventh modification will be described with reference to the drawings. FIG. 24 is a top view of the metal member 14g and an enlarged view of the metal member 14g.

The metal member 14g is different from the metal member 14 in that the support portions 202b to 202d are not provided. In the metal member 14g, the support portion 202a is located at the center of the metal member 14g in the left-right direction. Details will be described below.

The protruding portion P11 not including the left end and the right end of the lower end surface SD3 of the plate-shaped portion 140 is defined as a first intermediate protruding portion. The support portion 202a including the protruding portion P11 (first intermediate protruding portion) is defined as a first intermediate support portion. Two slits S1 and S3 are provided between the plate-shaped main body 200 and the support portion 202a (first intermediate support portion). Since other structures of the metal member 14g are the same as those of the metal member 14, the description thereof will be omitted.

### Eighth Modification

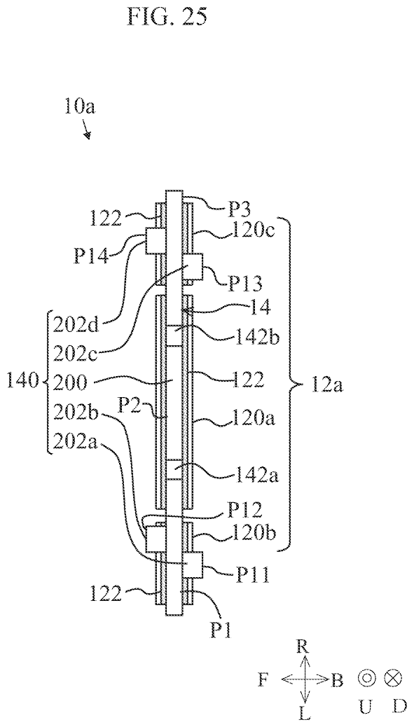

Hereinafter, a module 10a according to an eighth modification will be described with reference to the drawings. FIG. 25 is a top view of the metal member 14 and the mounting electrode 12a of the module 10a.

The module 10a is different from the module 10 in the shape of the mounting electrode 12a. In the module 10a, the mounting electrode 12a includes a mounting electrode central portion 120a, a mounting electrode left end portion 120b, and a mounting electrode right end portion 120c. That is, the mounting electrode 12a is divided into three parts. The mounting electrode central portion 120a overlaps the straight portion P2 when viewed in the up-down direction. The mounting electrode left end portion 120b overlaps the straight portion P1 and the support portions 202a and 202b when viewed in the up-down direction. The mounting electrode right end portion 120c overlaps the straight portion P3 and the support portions 202c and 202d when viewed in the up-down direction. Since other structures of the module 10a are the same as those of the module 10, description thereof is omitted.

### Ninth Modification

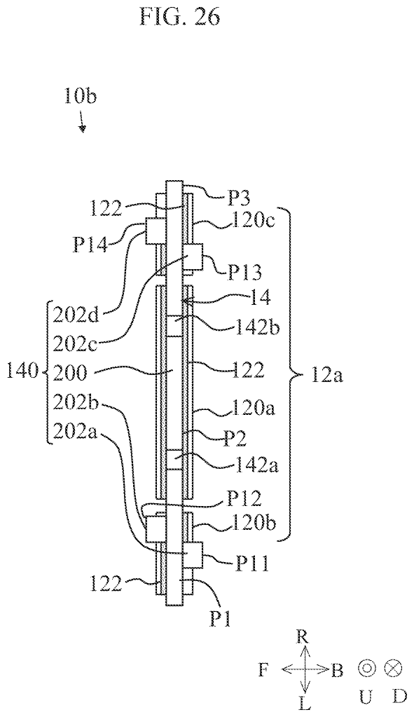

Hereinafter, a module 10b according to a ninth modification will be described with reference to the drawings. FIG. 26 is a top view of the metal member 14 and the mounting electrode 12a of the module 10b.

The module 10b is different from the module 10a in the shape of the solder 122. In the module 10b, the solder 122 is not provided under the support portions 202a to 202d. Since other structures of the module 10b are the same as those of the module 10, description thereof is omitted.

### Tenth Modification

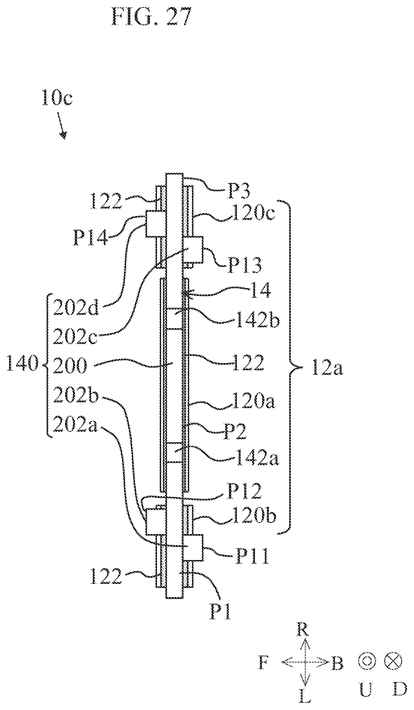

Hereinafter, a module 10c according to a tenth modification will be described with reference to the drawings. FIG. 27 is a top view of the metal member 14 and the mounting electrode 12a of the module 10c.

The module 10c is different from the module 10a in that the width of the mounting electrode central portion 120a is narrow. Thus, by adjusting the width of the mounting electrode central portion 120a, the amount of the solder 122 adhering to the plate-shaped main body 200 can be adjusted. Since other structures of the module 10c are the same as those of the module 10, description thereof is omitted.

According to the module 10c, since the width of the mounting electrode central portion 120a is narrow, the electronic component can be brought closer to the metal member 14.

In the module 10c, the solder 122 is provided before the protruding portions P11 and P13. As a result, the solder 122 is wetted on the front surfaces of the support portions 202a and 202c. Therefore, when the metal member 14 is mounted, the support portions 202a and 202c are pulled in the forward direction by the solder 122. On the other hand, the solder 122 is provided after the protruding portions P12 and P14. As a result, the solder 122 is wetted on the back surfaces of the support portions 202b and 202d. Therefore, when the metal member 14 is mounted, the support portions 202b and 202d are pulled in the backward direction by the solder 122. As a result, the force in the forward direction and the force in the backward direction acting on the metal member 14 are offset. As a result, the metal member 14 is mounted in an upright state. In particular, in the module 10c, since the width of the mounting electrode central portion 120a is narrow, the solder 122 is small. Even in the module 10c with less solder 122, the metal member 14 is suppressed from falling.

### Eleventh Modification

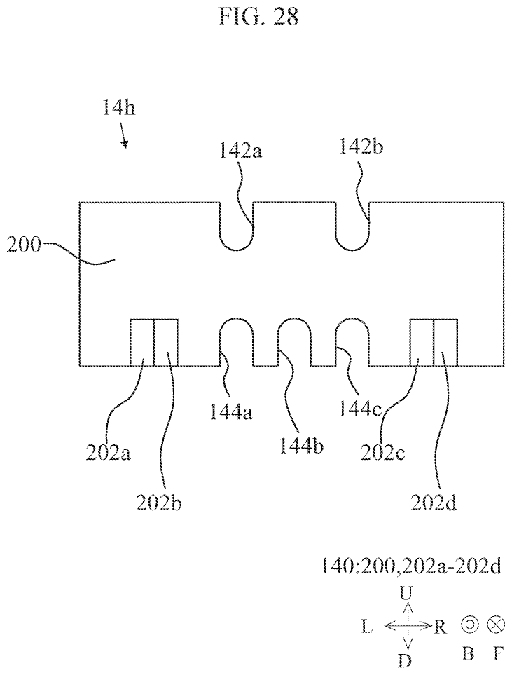

Hereinafter, a metal member 14h according to an eleventh modification will be described with reference to the drawings. FIG. 28 is a rear view of the metal member 14h.

The metal member 14h is different from the metal member 14 in that plate-shaped portion lower notches 144a to 144c are provided. More specifically, the plate-shaped portion 140 is provided with the plate-shaped portion lower notches 144a to 144c extending in the upward direction from the plate-shaped portion lower side LD. As a result, the molten resin can pass through the plate-shaped portion lower notches 144a to 144c in the front-back direction. As a result, the metal member 14h can be suppressed from falling. Since other structures of the metal member 14h are the same as those of the metal member 14, the description thereof will be omitted.

### Twelfth Modification

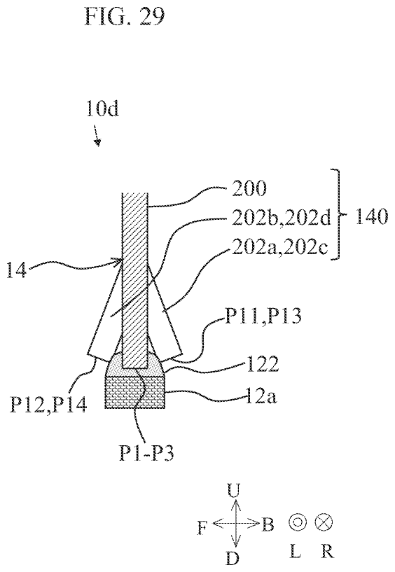

Hereinafter, a module 10d according to a twelfth modification will be described with reference to the drawings. FIG. 29 is a cross-sectional view of the metal member 14 of the module 10d.

The module 10d is different from the module 10 in a contact state between the metal member 14 and the solder 122. In the module 10d, the solder 122 is in contact with the plate-shaped main body 200 and the support portions 202a to 202d. More specifically, the solder 122 is provided before the protruding portions P11 and P13. As a result, the solder 122 is wetted on the front surfaces of the support portions 202a and 202c. The solder 122 is provided after the protruding portions P12 and P14. As a result, the solder 122 is wetted on the back surfaces of the support portions 202b and 202d. In the module 10d as described above, the plate-shaped main body 200 and the support portions 202a to 202d are fixed to the mounting electrode 12a by the solder 122. Since other structures of the module 10d are the same as those of the module 10, description thereof is omitted.

In the module 10d, the solder 122 is provided before the protruding portions P11 and P13. As a result, the solder 122 is wetted on the front surfaces of the support portions 202a and 202c. Therefore, when the metal member 14 is mounted, the support portions 202a and 202c are pulled in the forward direction by the solder 122. On the other hand, the solder 122 is provided after the protruding portions P12 and P14. As a result, the solder 122 is wetted on the back surfaces of the support portions 202b and 202d. Therefore, when the metal member 14 is mounted, the support portions 202b and 202d are pulled in the backward direction by the solder 122. As a result, the force in the forward direction and the force in the backward direction acting on the metal member 14 are offset. As a result, the metal member 14 is mounted in an upright state.

### Thirteenth Modification

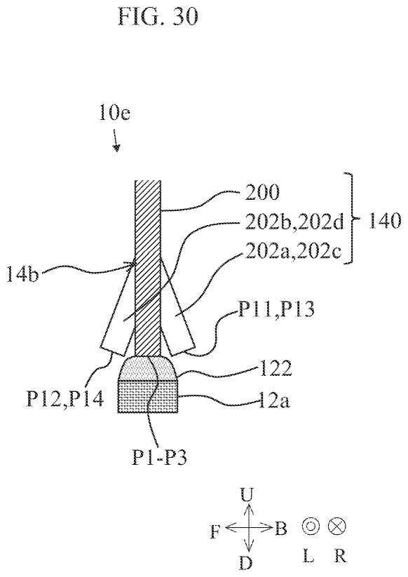

Hereinafter, a module 10e according to a thirteenth modification will be described with reference to the drawings. FIG. 30 is a cross-sectional view of the metal member 14b of the module 10e.

The module 10e is different from the module 10 in including a metal member 14b. More specifically, in the metal member 14b, the lower end of the plate-shaped main body 200 is fixed to the mounting electrode 12a by the solder 122. The support portions 202a to 202d are in contact with the solder 122. However, the solder 122 is not wetted with the support portions 202a to 202d. Since other structures of the module 10e are the same as those of the module 10, description thereof is omitted.

### Fourteenth Modification

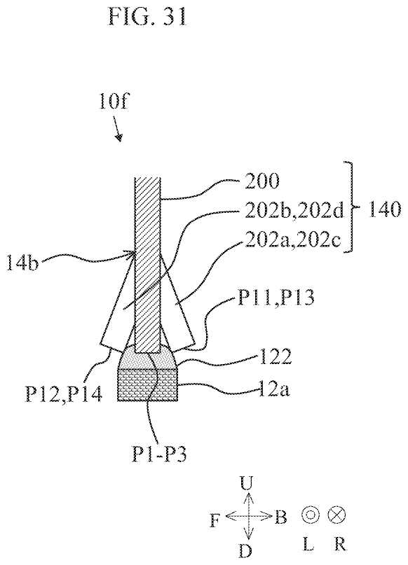

Hereinafter, a module 10f according to a fourteenth modification will be described with reference to the drawings. FIG. 31 is a cross-sectional view of the metal member 14b of the module 10f.

The module 10f is different from the module 10e in a contact state between the metal member 14b and the solder 122. In the module 10f, the solder 122 is in contact with the plate-shaped main body 200 and the support portions 202a to 202d. More specifically, the solder 122 is provided before the protruding portions P11 and P13. As a result, the solder 122 is wetted on the front surfaces of the support portions 202a and 202c. The solder 122 is provided after the protruding portions P12 and P14. As a result, the solder 122 is wetted on the back surfaces of the support portions 202b and 202d. In the module 10f as described above, the plate-shaped main body 200 and the support portions 202a to 202d are fixed to the mounting electrode 12a by the solder 122. Since other structures of the module 10f are the same as those of the module 10e, description thereof is omitted.

In the module 10f, the solder 122 is provided before the protruding portions P11 and P13. As a result, the solder 122 is wetted on the front surfaces of the support portions 202a and 202c. Therefore, when the metal member 14b is mounted, the support portions 202a and 202c are pulled in the forward direction by the solder 122. On the other hand, the solder 122 is provided after the protruding portions P12 and P14. As a result, the solder 122 is wetted on the back surfaces of the support portions 202b and 202d. Therefore, when the metal member 14b is mounted, the support portions 202b and 202d are pulled in the backward direction by the solder 122. As a result, the force in the forward direction and the force in the backward direction acting on the metal member 14b are offset. As a result, the metal member 14b is mounted in an upright state.

### Fifteenth Modification

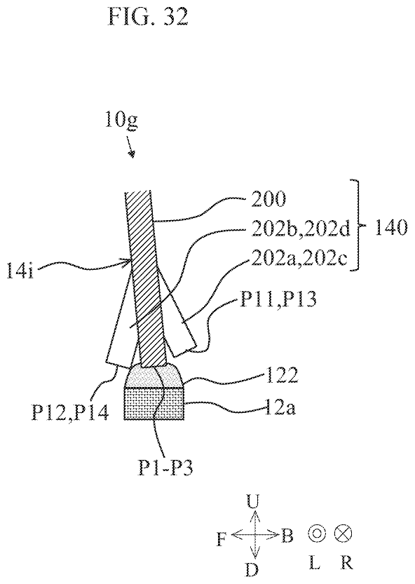

Hereinafter, a module 10g according to a fifteenth modification will be described with reference to the drawings. FIG. 32 is a cross-sectional view of a metal member 14i of the module 10g.

The module 10g differs from the module 10 in the structure of the metal member 14i. The lengths of the support portions 202a and 202c of the metal member 14i in the up-down direction are shorter than the lengths of the support portions 202b and 202d of the metal member 14 in the up-down direction. As a result, the metal member 14i is slightly inclined in the forward direction. Then, the solder 122 is wetted only on the front main surface of the plate-shaped main body 200. Since other structures of the module 10g are the same as those of the module 10, description thereof is omitted.

### Sixteenth Modification

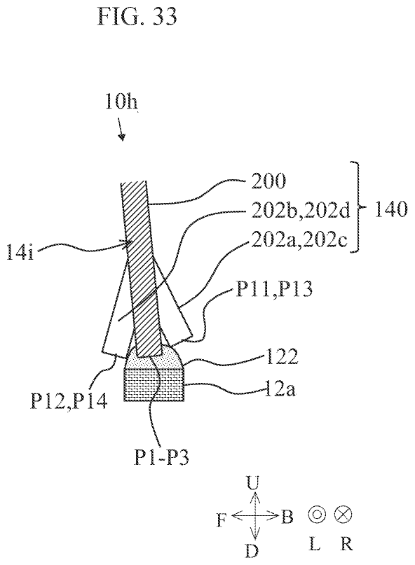

Hereinafter, a module 10h according to a sixteenth modification will be described with reference to the drawings. FIG. 33 is a cross-sectional view of the metal member 14i of the module 10h.

The module 10h is different from the module 10g in a contact state between the metal member 14i and the solder 122. More specifically, the solder 122 is wetted on the front main surface and the back main surface of the plate-shaped main body 200. Further, the solder 122 is also wetted with the support portions 202b and 202d. Since other structures of the module 10h are the same as those of the module 10g, description thereof is omitted.

### Seventeenth Modification

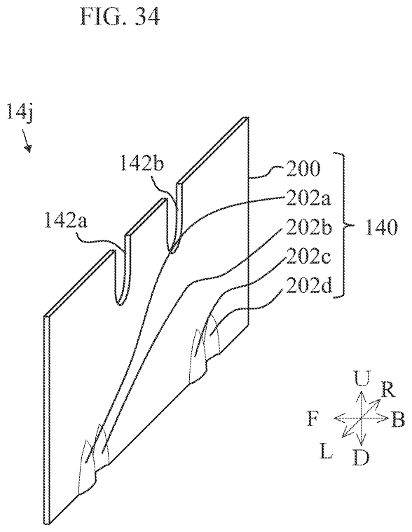

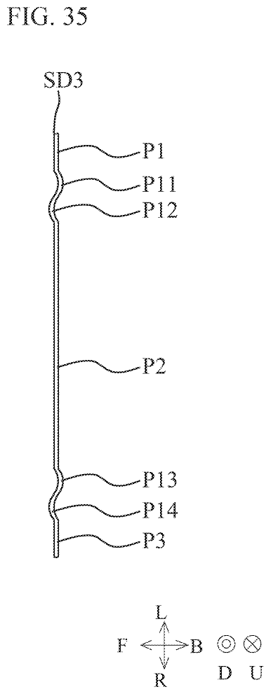

Hereinafter, a metal member 14j according to a seventeenth modification will be described with reference to the drawings. FIG. 34 is a perspective view of the metal member 14j. FIG. 35 is a view illustrating the lower end surface SD3 of the metal member 14j.

The metal member 14j is different from the metal member 14 in that the slits S1 to S6 are not provided. The support portions 202a and 202c are formed by slightly pushing out a part of the plate-shaped portion 140 in the backward direction by pressing. The support portions 202b and 202d are formed by slightly pushing out a part of the plate-shaped portion 140 in the forward direction by pressing. Therefore, the slits S1 to S6 are not provided in the metal member 14j. Therefore, in the metal member 14j, the straight portions P1 to P3 and the protruding portions P11 to P14 are connected. Since other structures of the metal member 14j are the same as those of the metal member 14, the description thereof will be omitted.

### OTHER EMBODIMENTS

The module and the metal member according to the present disclosure are not limited to the modules 10, and 10a to 10h and the metal members 14, and 14a to 14j according to the above embodiment, and can be changed within the scope of the gist thereof.

The structures of the modules 10, and 10a to 10h may be arbitrarily combined, or the structures of the metal members 14, and 14a to 14j may be arbitrarily combined.

The substrate 12 may have a shape other than a rectangular shape when viewed in the up-down direction.

The number of electronic components 16a to 16e is not limited to 5.

The module 10 may not include the shield 20.

The shield 20 may cover at least the upper surface SU1 of the sealing resin layer 18. Therefore, the shield 20 may not cover a part or all of the left surface SL1, the right surface SR1, the front surface SF1, and the back surface SB1 of the sealing resin layer 18, for example.

Incidentally, the outer edge of the substrate 12 may not overlap so as to coincide with the outer edge of the sealing resin layer 18 when viewed in the up-down direction. That is, the front surface SF1 of the sealing resin layer 18 may be located before the front surface SF2 of the substrate 12. The back surface SB1 of the sealing resin layer 18 may be located after the back surface SB2 of the substrate 12. The left surface SL1 of the sealing resin layer 18 may be located to the left of the left surface SL2 of the substrate 12. The right surface SR1 of the sealing resin layer 18 may be located to the right of the right surface SR2 of the substrate 12.

The electronic components 16a to 16e do not protrude in the left direction or in the right direction from the metal member 14 when viewed in the front-back direction. However, a part of the electronic components 16a to 16e may protrude in the left direction or in the right direction from the metal member 14 when viewed in the front-back direction.

The number of protruding portions may be one or more. Similarly, the number of support portions may be one or more.

The number of plate-shaped portion upper notches may be one or more. In addition, the number of plate-shaped portion lower notches may be one or more.

All of the one or more protruding portions may protrude in the forward direction with respect to the plate-shaped main body 200, or all of the one or more protruding portions may protrude in the backward direction with respect to the plate-shaped main body 200.

The slits S1 to S6 extend linearly in the upward direction, but may be curved or meandering.

The metal member may include both the end support portion and the intermediate support portion.

The metal member may have a bent portion extending in the forward direction or the backward direction from the left end or the right end of the plate-shaped portion 140. In this case, the bent portion is formed, for example, by bending a part of the metal member in the forward direction or the backward direction with respect to the plate-shaped portion 140.

The solder 122 provided on the mounting electrode 12a may be divided into a plurality of parts. In addition, the solder 122 provided in the mounting electrode central portion 120a may also be divided into a plurality of parts.

The mounting electrode left end portion 120b may not overlap the support portion 202a. The mounting electrode left end portion 120b may not overlap the support portion 202b. The mounting electrode right end portion 120c may not overlap the support portion 202c. The mounting electrode right end portion 120c may not overlap support portion 202d.

The solder 122 is an example of a conductive bonding material. The conductive bonding material is, for example, solder, a conductive adhesive, or the like. The conductive adhesive is an adhesive in which a conductive metal powder is dispersed in a resin.

Note that the slots (first slot, second slot, and third slot) may be provided instead of the slits S1 to S6 (first slit, second slit, and third slit). The slit and the slot are spaces formed by providing a recess having a constant width in the metal member 14 before bending.
10, 10a to 10h module
12 substrate
12a mounting electrode
14, 14a to 14j metal member
16a to 16e electronic component
18 sealing resin layer
20 shield
120a mounting electrode central portion
120b mounting electrode left end portion
120c mounting electrode right end portion
122 solder
140 plate-shaped portion
142a, 142b plate-shaped portion upper notch
144a to 144c plate-shaped portion lower notch
149 top surface portion
200 plate-shaped main body
202a to 202d support portion
600 mounting machine
G ground conductor layer
LD plate-shaped portion lower side
LU plate-shaped portion upper side
P1 to P3 straight portion
P11 to P14 protruding portion
S1 to S6 slit

1. A module comprising:
a substrate having an upper main surface and a lower main surface arranged in an up-down direction;
a metal member including a plate-shaped portion provided on the upper main surface of the substrate, the plate-shaped portion having:
a front main surface and a back main surface arranged in a front-back direction when viewed in the up-down direction, and
a lower end surface connected to the front main surface and the back main surface;
a first electronic component mounted on the upper main surface of the substrate and disposed before the metal member;
a second electronic component mounted on the upper main surface of the substrate and disposed after the metal member; and
a sealing resin layer provided on the upper main surface of the substrate and covering the metal member, the first electronic component, and the second electronic component, wherein:
a lower end surface of the plate-shaped portion includes:
a straight portion extending in a left-right direction; and
one or more protruding portions extending in a forward direction or a backward direction with respect to the straight portion; and
the straight portion and the one or more protruding portions are visually recognized when viewed in an upward direction.

2. The module according to claim 1, wherein
the plate-shaped portion includes:
a plate-shaped main body including the straight portion and having a flat plate shape; and
one or more support portions including the one or more protruding portions and protruding in a forward direction or a backward direction with respect to the plate-shaped main body.

3. The module according to claim 2, wherein
when viewed in the front-back direction, a line connecting lower ends of the plate-shaped portion in the left-right direction is defined as a plate-shaped portion lower side, and
one or more slits or one or more slots extending in an upward direction from the plate-shaped portion lower side are provided between the plate-shaped main body and the support portions.

4. The module according to claim 3, wherein
a protruding portion including a left end or a right end of a lower end of the plate-shaped portion among the one or more protruding portions is defined as an end protruding portion,
a support portion including the end protruding portion among the one or more support portions is defined as an end support portion, and
one of the slits or the slots is provided between the plate-shaped main body and the end support portion.

5. The module according to claim 3, wherein
a protruding portion not including a left end and a right end of a lower end of the plate-shaped portion among the one or more protruding portions is defined as a first intermediate protruding portion,
a support portion including the first intermediate protruding portion among the one or more support portions is defined as a first intermediate support portion, and
two of the slits or the slots are provided between the plate-shaped main body and the first intermediate support portion.

6. The module according to claim 3, wherein
a protruding portion not including a left end and a right end of a lower end of the plate-shaped portion among the one or more protruding portions is defined as a first intermediate protruding portion and a second intermediate protruding portion,
a support portion including the first intermediate protruding portion among the one or more support portions is defined as a first intermediate support portion,
a support portion including the second intermediate protruding portion among the one or more support portions is defined as a second intermediate support portion,
the first intermediate protruding portion and the second intermediate protruding portion are adjacent to each other in the left-right direction,
the first intermediate protruding portion protrudes in a backward direction with respect to the plate-shaped main body,
the second intermediate protruding portion protrudes in a forward direction with respect to the plate-shaped main body,
a first slit or a first slot extending in an upward direction from the plate-shaped portion lower side is provided between the plate-shaped main body and the first intermediate support portion,
a second slit or a second slot extending in the upward direction from the plate-shaped portion lower side is provided between the first intermediate support portion and the second intermediate support portion, and
a third slit or a third slot extending in the upward direction from the plate-shaped portion lower side is provided between the plate-shaped main body and the second intermediate support portion.

7. The module according to claim 1, wherein the straight portion and the one or more protruding portions are connected.

8. The module according to claim 1, wherein
when viewed in the front-back direction, a line connecting a lower end of the plate-shaped portion in the left-right direction is defined as a plate-shaped portion lower side, and
one or more plate-shaped portion lower notches extending in an upward direction from the plate-shaped portion lower side are provided in the plate-shaped portion.

9. The module according to claim 1, wherein
the substrate includes a mounting electrode located on the upper main surface of the substrate, and
the straight portion is fixed to the mounting electrode by a conductive bonding material.

10. The module according to claim 9, wherein
the one or more protruding portions protrude in the forward direction with respect to the straight portion, and the conductive bonding material is provided after the one or more protruding portions, or
the one or more protruding portions protrude in the backward direction with respect to the straight portion, and the conductive bonding material is provided before the one or more protruding portions.

11. The module according to claim 9, further comprising a shield covering an upper surface of the sealing resin layer,
wherein the metal member is electrically connected to the shield via the mounting electrode.

12. The module according to claim 1, wherein an upper end of the plate-shaped portion is located on an upper surface of the sealing resin layer.

13. The module according to claim 4, wherein
a protruding portion not including a left end and a right end of a lower end of the plate-shaped portion among the one or more protruding portions is defined as a first intermediate protruding portion,
a support portion including the first intermediate protruding portion among the one or more support portions is defined as a first intermediate support portion, and
two of the slits or the slots are provided between the plate-shaped main body and the first intermediate support portion.

14. The module according to claim 4, wherein
a protruding portion not including a left end and a right end of a lower end of the plate-shaped portion among the one or more protruding portions is defined as a first intermediate protruding portion and a second intermediate protruding portion,
a support portion including the first intermediate protruding portion among the one or more support portions is defined as a first intermediate support portion,
a support portion including the second intermediate protruding portion among the one or more support portions is defined as a second intermediate support portion,
the first intermediate protruding portion and the second intermediate protruding portion are adjacent to each other in the left-right direction,
the first intermediate protruding portion protrudes in a backward direction with respect to the plate-shaped main body,
the second intermediate protruding portion protrudes in a forward direction with respect to the plate-shaped main body,
a first slit or a first slot extending in an upward direction from the plate-shaped portion lower side is provided between the plate-shaped main body and the first intermediate support portion,
a second slit or a second slot extending in the upward direction from the plate-shaped portion lower side is provided between the first intermediate support portion and the second intermediate support portion, and
a third slit or a third slot extending in the upward direction from the plate-shaped portion lower side is provided between the plate-shaped main body and the second intermediate support portion.

15. The module according to claim 5, wherein
a protruding portion not including a left end and a right end of a lower end of the plate-shaped portion among the one or more protruding portions is defined as a first intermediate protruding portion and a second intermediate protruding portion,
a support portion including the first intermediate protruding portion among the one or more support portions is defined as a first intermediate support portion,
a support portion including the second intermediate protruding portion among the one or more support portions is defined as a second intermediate support portion,
the first intermediate protruding portion and the second intermediate protruding portion are adjacent to each other in the left-right direction,
the first intermediate protruding portion protrudes in a backward direction with respect to the plate-shaped main body,
the second intermediate protruding portion protrudes in a forward direction with respect to the plate-shaped main body,
a first slit or a first slot extending in an upward direction from the plate-shaped portion lower side is provided between the plate-shaped main body and the first intermediate support portion,
a second slit or a second slot extending in the upward direction from the plate-shaped portion lower side is provided between the first intermediate support portion and the second intermediate support portion, and
a third slit or a third slot extending in the upward direction from the plate-shaped portion lower side is provided between the plate-shaped main body and the second intermediate support portion.

16. The module according to claim 2, wherein the straight portion and the one or more protruding portions are connected.

17. The module according to claim 2, wherein
when viewed in the front-back direction, a line connecting a lower end of the plate-shaped portion in the left-right direction is defined as a plate-shaped portion lower side, and one or more plate-shaped portion lower notches extending in an upward direction from the plate-shaped portion lower side are provided in the plate-shaped portion.

18. The module according to claim 3, wherein
when viewed in the front-back direction, a line connecting a lower end of the plate-shaped portion in the left-right direction is defined as a plate-shaped portion lower side, and one or more plate-shaped portion lower notches extending in an upward direction from the plate-shaped portion lower side are provided in the plate-shaped portion.

19. The module according to claim 4, wherein
when viewed in the front-back direction, a line connecting a lower end of the plate-shaped portion in the left-right direction is defined as a plate-shaped portion lower side, and one or more plate-shaped portion lower notches extending in an upward direction from the plate-shaped portion lower side are provided in the plate-shaped portion.

20. The module according to claim 5, wherein
when viewed in the front-back direction, a line connecting a lower end of the plate-shaped portion in the left-right direction is defined as a plate-shaped portion lower side, and one or more plate-shaped portion lower notches extending in an upward direction from the plate-shaped portion lower side are provided in the plate-shaped portion.
